(19) United States
(12) Patent Application Publication
(10) Pub. No.: US 2019/0390318 A1
(43) Pub. Date: Dec. 26, 2019

(54) MASK ASSEMBLIES

(71) Applicant: Kunshan Go-Visionox Opto-Electronics Co., Ltd., Kunshan (CN)

(72) Inventors: Jinfang Zhang, Kunshan (CN); Lu Zhang, Kunshan (CN); Zhenzhen Han, Kunshan (CN); Siming Hu, Kunshan (CN)

(21) Appl. No.: 16/562,446

(22) Filed: Sep. 6, 2019

Related U.S. Application Data
(63) Continuation of application No. PCT/CN2018/089386, filed on May 31, 2018.

(30) Foreign Application Priority Data
Oct. 31, 2017 (CN) 201711051595.3

(51) Int. Cl. C23C 14/04; B05C 1/02; H01L 51/00

(52) U.S. Cl. CPC C23C 14/042; H01L 51/0011; B05C 1/027

(57) ABSTRACT

The present disclosure relates to a mask assembly adapted for being applied in an evaporation process of preparing a display screen. The mask assembly includes a mask provided with a plurality of opening areas, an evaporation material is deposited through the plurality of opening areas; and a plurality of opening area shielding members disposed at edges of the plurality of opening areas and configured to shield a portion of the evaporation material, so as to form a display chamfer on the display screen in the evaporation process.

### CROSS-REFERENCE TO RELATED APPLICATIONS

This application is a continuation application of International Application PCT/CN2018/089386, filed on May 31, 2018, which claims the priority benefit of Chinese Patent Application No. 201711051595.3, titled “MASK ASSEMBLIES” and filed on Oct. 31, 2017. The entireties of these applications are incorporated by reference herein for all purposes.

### TECHNICAL FIELD

The present disclosure relates to the field of irregular-shaped display.

### BACKGROUND TECHNOLOGY

With the development of electronic technology, electronic display screens have become more and more diverse, and irregular-shaped display screens such as round-angle display screens and curved screens appear.

In conventional art, an OLED (Organic Light-Emitting Diode) display screen has an effective display area defined by a contour line. Corresponding pixels or sub-pixels are arranged along the contour line to fit a shape of the contour line. When a non-linear portion is present in the contour line, with respect to a portion of the non-linear contour line, pixels or sub-pixels arranged along the contour line are typically stepped or serrated. For example, when the display screen is designed with a chamfer as desired, pixels or sub-pixels arranged along the chamfer are generally stepped or serrated.

Applicants have found in the process of implementing:

When a non-linear portion is present in the contour line, with respect to a portion of the non-linear contour line, pixels or sub-pixels arranged along the contour line are arranged in steps, and the number of sub-pixels in different columns is different, which requires that the number of sub-pixel opening areas in different columns on a corresponding fine metal mask is also different, so that openings of the fine metal mask are irregular, thereby affecting the tensioning and accuracy adjustment thereof.

### SUMMARY

According to various embodiments disclosed in the present disclosure, a mask assembly adapted for being applied in an evaporation process of preparing a display screen is provided, and the mask assembly includes: a mask provided with a plurality of opening areas, an evaporation material is deposited through the plurality of opening areas; and a plurality of opening area shielding members disposed at edges of the plurality of opening areas and configured to shield a portion of the evaporation material, so as to form a display chamfer on the display screen in the evaporation process.

In one of the embodiments, at least a portion of the opening area shielding member is disposed at a corner of the opening area.

In one of the embodiments, the opening area shielding member is soldered to the corner of the opening area.

In one of the embodiments, a thickness of the opening area shielding member is same to a thickness of the mask.

In one of the embodiments, the mask assembly further includes a mask attachment, and the opening area shielding member is fixed to the mask attachment.

In one of the embodiments, the mask assembly includes a plurality of opening area shielding members, the plurality of opening area shielding members are fixed to the mask attachment and distributed in an array.

In one of the embodiments, the mask attachment is capable of translating with respect to the mask.

In one of the embodiments, the mask assembly and the mask are fixed to a frame, the frame is provided with a slide rail on the frame, and the mask attachment is capable of translating with respect to the mask via the slide rail.

In one of the embodiments, the mask attachment is capable of rotating with respect to the mask.

In one of the embodiments, the mask assembly and the mask are fixed to a frame, the frame is provided with a slide rail on the frame, and the mask attachment is capable of rotating with respect to the mask via the slide rail.

In one of the embodiments, the mask attachment and the mask have a common rotating shaft.

In one of the embodiments, the frame is provided with a limiting member.

In one of the embodiments, a contour line of a portion of the opening area shielding member for forming the display chamfer is formed into a smooth arc.

In one of the embodiments, a contour line of a portion of the opening area shielding member for forming the display chamfer is formed into a stepped polygonal line.

In the present disclosure, by providing the opening area shielding member in the mask assembly for shielding positions in the opening filed other than the corresponding predetermined evaporation position to form the display chamfer, the mask may be made into a shape that facilitates tensioning and accuracy adjustment thereof, thereby improving the problems of the tensioning and accuracy adjustment of the mask in the manufacturing of an irregular-shaped display screen.

### BRIEF DESCRIPTION OF THE DRAWINGS

FIG. 1 is a schematic view of an evaporation device according to the prior art.

FIG. 2 is a schematic view of a mask assembly according to an embodiment of the present disclosure.

FIG. 3 is a schematic view of a mask attachment according to an embodiment of the present disclosure.

### DETAILED DESCRIPTION OF THE EMBODIMENTS

In Organic Light-Emitting Diode (OLED) display technology, an OLED display screen is typically obtained by using evaporation technology. A typical structure of the OLED display screen is that, a layer of light-emitting materials having a thickness of tens of nanometers is evaporated on a TFT (thin film transistor) substrate provided with an anode, and then a layer of cathode is evaporated on the light-emitting materials. After a voltage is applied across the cathode and the anode, the light-emitting layer emits light.

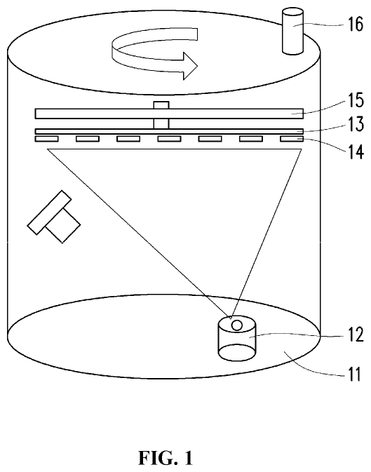

The light-emitting materials are the main evaporation materials. The light-emitting material is evaporated on the TFT substrate and the light-emitting layer is formed. Referring to FIG. 1, FIG. 1 is a schematic view of an evaporation device. The evaporation device includes a vacuum chamber 11, and an evaporation source 12, a TFT substrate 13, a mask 14, a magnetic plate 15, and an alignment system 16 placed within the vacuum chamber 11.

In the vacuum chamber 11, the TFT substrate 13 is placed on a rotating sample holder. The evaporation materials such as the light-emitting materials or metal electrode materials are heated to evaporate the evaporation materials into gaseous atoms or molecules. The gaseous atoms or molecules undergo Brownian motion in the vacuum chamber, and condense on a surface of the TFT substrate 13 to form a thin film after colliding with the TFT substrate 13. The method for heating the evaporation material includes one or more of current heating, electron beam bombardment heating, laser heating, or the like.

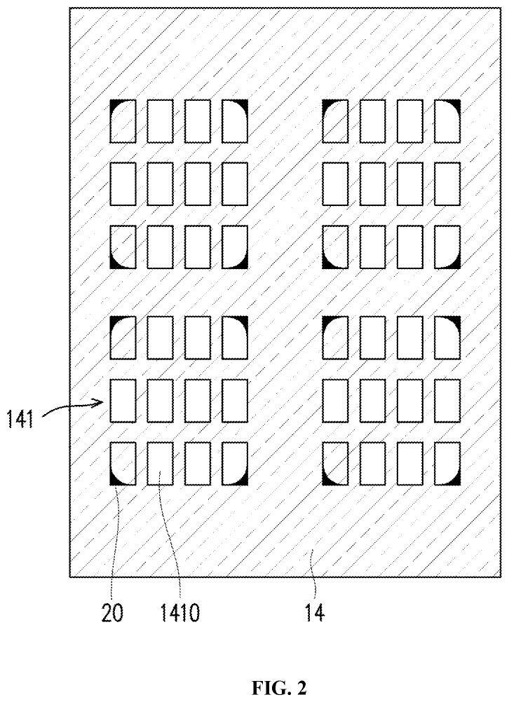

Referring to FIG. 2, in order to accurately control the position of the light-emitting material during the evaporation process, a fine metal mask (FMM) is generally required. The fine metal mask is provided with an opening area 141 to evaporate a complete display screen. The opening area 141 includes a plurality of sub-openings 1410. Each of the sub-openings 1410 corresponds to one sub-pixel. The sub-pixels may generally include a first sub-pixel, a second sub-pixel, and a third sub-pixel. The first sub-pixel, the second sub-pixel, and the third sub-pixel may generally be a red sub-pixel, a green sub-pixel, and a blue sub-pixel, respectively. During the evaporation process, the red sub-pixel, the green sub-pixel, and the blue sub-pixel are usually evaporated separately. In order to prevent misalignment between sub-pixels, a shielding strip may generally be used to shield the unwanted sub-openings 1410 to evaporate the required sub-pixels separately.

With the development of the display screen technology, there is a demand for providing a chamfer on the display screen to improve the display effect. In order to satisfy this requirement, a shape of the shielding strip may be changed so that a display screen having a chamfer can be evaporated. However, when the shielding strip is provided with a corresponding chamfered structure, the shielding strip is easily wrinkled due to stress concentration.

Referring to FIG. 2, according to an embodiment of the present disclosure, a mask assembly adapted for being applied in an evaporation process of preparing a display screen is provided, which includes:

a mask 14 provided with a plurality of opening areas 141, an evaporation material is deposited through the plurality of opening areas 141; and

a plurality of opening area shielding members 20 disposed at edges of the plurality of opening areas 141 and configured to shield a portion of the evaporation material, so as to form a display chamfer on the display screen in the evaporation process.

The mask 14 is used to control a predetermined position of an organic material deposited on the substrate. As mentioned above, the mask 14 is provided with the opening area 141. The opening area 141 may generally correspond to a display screen of a complete product. The opening area 141 includes a plurality of sub-openings 1410. Each of the sub-openings 1410 corresponds to one sub-pixel. In order to accurately control the position at which the organic material is deposited, the mask 14 may use the fine metal mask. The fine metal mask can be made of SUS (steel use stainless) 420 or SUS 430.

The opening area shielding member 20 shields in the evaporation direction of the opening area 141 to form the display chamfer of the display screen. In other words, the opening area shielding member 20 can correspond to the display chamfer of the display screen. In order to ensure accuracy, the opening area shielding member 20 may also be made of SUS 420 or SUS 430.

In addition, in an embodiment of the present disclosure, the opening area shielding member 20 is disposed at a corner of the opening area 141.

In order to form the display chamfer of the display screen, at least a portion of the opening area shielding member 20 must be disposed at a corner of the opening area 141. In this way, during the evaporation process, the evaporation material is deposited on the opening area shielding member 20 without being further deposited on a position other than the predetermined position through the opening area shielding member 20.

Moreover, in an embodiment of the present disclosure, the opening area shielding member 20 is soldered to a corner of the opening area 141.

The opening area shielding member 20 is soldered to the corner of the opening area 141, so that when a thickness of the opening area shielding member 20 is same to a thickness of the mask 14, a portion of the opening area 141 that is not shielded by the opening area shielding member 20 may be deposited with the evaporation material. When the opening area shielding member 20 is located upstream of the mask 14 in the evaporation direction, some evaporation material may be diffused and deposited downstream of the opening area shielding member 20 in the evaporation direction, thereby reducing the quality of the evaporation. In the embodiment of the present disclosure, when the opening area shielding member 20 is soldered to the opening area 141, the quality of the evaporation can be improved.

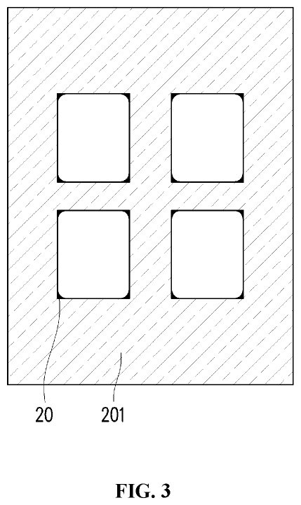

Referring to FIG. 3, furthermore, in an embodiment of the present disclosure, the mask assembly further includes a mask attachment 201, and the opening area shielding member 20 is fixed to the mask attachment 201.

It can be seen from the previous description that, when the opening area shielding member 20 is soldered to the mask 14, the existing mask 14 is required to be retrofitted, and the quality of the soldering or the fixed connection will eventually affect the quality of the evaporation. In this embodiment, when the opening area shielding member 20 is fixed to the mask attachment 201, it is not necessary to retrofit the original mask 14 so as to prevent poor accuracy during the two processing and manufacturing, thereby improving the quality of the evaporation.

In addition, in an embodiment of the present disclosure, the mask assembly further includes a mask attachment 201. A plurality of opening area shielding members 20 are fixed to the mask attachment 201 and distributed in an array.

In this embodiment of the present disclosure, the opening area shielding members 20 are fixed to the mask attachment 201 and distributed in an array, so that a plurality of display screens with chamfers can be manufactured at one time, and the production efficiency can be effectively improved.

Moreover, in an embodiment of the present disclosure, the mask attachment 201 is capable of translating with respect to the mask 14.

Generally, the mask 14 may be fixed by a frame. Here, the mask attachment 201 may also be fixed by the frame. A slide rail of the mask attachment 201 may be provided on the frame. Thus, the mask attachment 201 can be translated with respect to the mask 14 via the slide rail. A limiting member, such as a limiting screw or the like, may be provided on the frame. The translation of the mask attachment 201 with respect to the mask 14 can adjust the position of the opening area shielding member 20 with respect to the opening area 141. When the position of the mask attachment 201 with respect to the mask 14 is adjusted to an appropriate position, the mask attachment 201 is limited by using the limiting member. Thus, the display screen having the chamfer can be conveniently manufactured.

Furthermore, in another embodiment of the present disclosure, the mask attachment 201 is capable of rotating with respect to the mask 14.

In addition, in yet another embodiment of the present disclosure, the mask attachment 201 and the mask 14 have a common rotating shaft.

Generally, the mask 14 may be fixed by a frame. Here, the mask attachment 201 may also be fixed by the frame. The rotating shaft may be provided on the frame. Thus, the mask attachment 201 can rotate with respect to the mask 14 about the rotating shaft. A limiting member, such as a limiting screw or the like, may be provided on the frame. The rotation of the mask attachment 201 with respect to the mask 14 can adjust the position of the opening area shielding member 20 with respect to the opening area 141. When the position of the mask attachment 201 with respect to the mask 14 is adjusted to an appropriate position, the limiting member is used to limit the mask attachment 201. Thus, the display screen having the chamfer can be conveniently manufactured.

The rotating shaft may also be disposed on the mask 14, and the mask attachment 201 and the mask 14 having a common rotating shaft.

In addition, in still another embodiment of the present disclosure, a contour line of a portion of the opening area shielding member 20 for forming the chamfer is formed into a smooth arc.

When the contour line of the portion for forming the chamfer in the microstructure of the opening area shielding member 20 is a smooth arc, correspondingly, at least a portion of the sub-pixel obtained by the deposition has a shape corresponding to the smooth arc, so that the serration at the chamfer can be reduced.

Moreover, in still another embodiment of the present disclosure, a contour line of a portion of the opening area shielding member 20 for forming the chamfer is formed into a stepped polygonal line.

When the contour line of the portion for forming the chamfer in the microstructure of the opening area shielding member 20 is a stepped polygonal line, the formed sub-pixel is a complete sub-pixel, and the driver of the sub-pixel does not have to be adaptively retrofitted, so that the use range of the opening area shielding member 20 can be expanded.

The following describes a specific application scenario in which the present disclosure is implemented:

In preparing the display screen having the chamfer, the mask 14 is fixed to the frame, while the opening area shielding member 20 shields the opening area 141 of the mask 14 to form the chamfer.

In one implementation provided in the present disclosure, the opening area shielding member 20 may be fixed to the opening area 141 of the mask 14. The fixed method may be a conventional connection means such as soldering, bonding, adsorption, and the like.

In another implementation provided in the present disclosure, the opening area shielding member 20 may be fixed to the mask attachment 201, and the position of the opening area shielding member 20 with respect to the opening area 141 can be adjusted by the relative movement between the mask attachment 201 and the mask 14, so that the mask attachment 201 and the mask 14 are adjusted to an appropriate position. The mask attachment 201 may be translated with respect to the mask 14, or may be rotated with respect to the mask 14. In addition, the mask attachment 201 may also have a common rotating shaft with the mask 14.

When the position of the opening area shielding member 20 with respect to the mask 14 is adjusted to an appropriate position, the evaporation atmosphere is turned on to perform evaporation.

The foregoing embodiments are merely illustrative of several embodiments of the present disclosure, and the description thereof is more specific and detailed, but is not to be construed as limiting the scope of the disclosure. It should be noted that any variation or replacement readily figured out by a person skilled in the art without departing from the concept of the present disclosure shall all fall within the protection scope of the present disclosure. Therefore, the protection scope of the present disclosure shall be subject to the protection scope of the appended claims.

1. A mask assembly, adapted for being applied in an evaporation process of preparing a display screen, the mask assembly comprising:
a mask provided with a plurality of opening areas, an evaporation material being deposited through the plurality of opening areas; and
a plurality of opening area shielding members disposed at edges of the plurality of opening areas and configured to shield a portion of the evaporation material to form a display chamfer on the display screen in the evaporation process.

2. The mask assembly of claim 1, wherein at least a portion of the opening area shielding member is disposed at a corner of the opening area.

3. The mask assembly of claim 2, wherein the opening area shielding member is soldered to the corner of the opening area.

4. The mask assembly of claim 3, wherein a thickness of the opening area shielding member is same to a thickness of the mask.

5. The mask assembly of claim 2, further comprising a mask attachment, the opening area shielding member being fixed to the mask attachment.

6. The mask assembly of claim 2, further comprising a mask attachment, wherein the plurality of opening area shielding members are fixed to the mask attachment and distributed in an array.

7. The mask assembly of claim 6, wherein the mask attachment is capable of translating with respect to the mask.

8. The mask assembly of claim 7, wherein the mask assembly and the mask are fixed to a frame, the frame is provided with a slide rail on the frame, and the mask attachment is capable of translating with respect to the mask via the slide rail.

9. The mask assembly of claim 8, wherein the frame is further provided with a limiting member, the mask attachment is capable of being limited by the limiting member.

10. The mask assembly of claim 6, wherein the mask attachment is capable of rotating with respect to the mask.

11. The mask assembly of claim 10, wherein the mask assembly and the mask are fixed to a frame, the frame is provided with a rotating shaft on the frame, and the mask attachment is capable of rotating with respect to the mask via the rotating shaft.

12. The mask assembly of claim 11, wherein the frame is provided with a limiting member, the mask attachment is capable of being limited by the limiting member.

13. The mask assembly of claim 10, wherein the mask attachment and the mask have a common rotating shaft.

14. The mask assembly of claim 1, wherein a contour line of a portion of the opening area shielding member for forming the display chamfer is formed into a smooth arc.

15. The mask assembly of claim 1, wherein a contour line of a portion of the opening area shielding member for forming the display chamfer is formed into a stepped polygonal line.
